(19) United States
(12) Patent Application Publication
(10) Pub. No.: US 2025/0072300 A1
(43) Pub. Date: Feb. 27, 2025

(54) Tuneable Qubit Circuit Employing Twist Couplers

(71) Applicants: University of Copenhagen, Copenhagen K (DK); Aarhus Universitet, Aarhus C (DK)

(72) Inventors: Kasper Sangild Christensen, Aarhus N (DK); Nikolaj Thomas Zinner, Aarhus C (DK); Morten Kjærgaard, Copenhagen Ø (DK); András Gyenis, Copenhagen Ø (DK)

(21) Appl. No.: 18/724,232

(22) PCT Filed: Jan. 6, 2023
(86) PCT No.: PCT/EP2023/050239

§ 371 Date: Jun. 26, 2024

(30) Foreign Application Priority Data
Jan. 6, 2022 (EP) 22150429

(51) Int. Cl. H10N 69/00; G06N 10/20; G06N 10/70; H10N 60/12

(52) U.S. Cl. CPC H10N 69/00; G06N 10/20; G06N 10/70; H10N 60/12

(57) ABSTRACT

The present disclosure regards a qubit circuit comprising at least first and second data qubits and a mediator qubit coupling the first and second data qubits in a circuit plane, wherein the first data qubit and the second data qubit are coupled to the mediator qubit by means of respective twist couplers, each twist coupler comprising superconducting regions connected by superconducting transmission lines, wherein at least two of the connecting transmission lines cross each other at a line crossing point where the crossing transmission lines are separated by an insulator layer.

The present disclosure relates to superconducting qubit circuits. In particular, the present disclosure relates to a circuit design comprising qubit couplers with twisted transmission lines enabling tuning of the inter-qubit coupling.

### BACKGROUND

Quantum computers are expected to solve in a fast and reliable manner complex computation problems that would require years to compute in the fastest available supercomputers. Quantum bits, or qubits, are the building block of such a quantum computer and they can be realized by any two energy level quantum system were information is encoded in a superposition of states, as opposed to classical bits where only two defined states are possible. The physical realization of the hardware hosting reliable qubits is challenging since they are prone to error generation during the qubit operations, making this approach difficult to scale into useful processor sizes.

A superconducting qubit is a type of qubit that uses the properties of superconductors and the energy levels created by them. They are mostly constituted by combinations of nanodevices such as Josephson junctions, capacitors, inductances and transmission lines that control, operate and measure the qubit outputs.

Furthermore, superconductor qubits offer a scalable platform for quantum processors and a high fidelity compared to other platforms. Optical qubits can be operated at room temperature although they are complicated to escalate into processors with enough qubits to perform useful operations, due to the qubit size restrictions. Solid state qubits, employing for example the spin, impurities, topological and superconducting approaches, necessitate operation in cryostats that are able to reach temperatures in the order of mili-kelvin, although they also offer an excellent scalability potential due to their reduced size.

In order to fabricate reliable superconducting qubits, it is essential to allow the superposition of states between different qubits in a controlled way. For this reason, coupler devices are responsible to allow and prevent a degree of interaction between qubits. Large coupling constant g is desired for such coupling devices, implying that they allow a high degree of qubit-qubit interaction when needed and they isolate both qubits the rest of the time.

### SUMMARY

The present disclosure regards a novel type of qubit coupler, referred to herein as a twist coupler, that enables the desired large coupling constant when implemented as a tuneable superconducting qubit coupler. When implemented into scalable circuits, the presently disclosed twist coupler solves the above-mentioned demands to fabricate a quantum computer.

The presently disclosed qubit coupler, aka twist coupler, for coupling two superconductor qubits comprises superconducting regions connected by superconducting transmission lines, wherein at least two of the connecting transmission lines cross each other at a line crossing point where the crossing transmission lines are separated by an insulator layer, forming a Josephson junction.

Preferably the superconducting regions and the transmission lines are provided on a substrate as (selective deposition) layers having a thickness of between 5 and 200 nm and preferably a length between 1 and 100 μm. The insulator layer(s) preferably has a thickness of less than 30 nm. See FIGS. 1 and 2 for schematic illustrations of twist couplers.

The presently disclosed twist coupler allows the provision of qubit circuits and in particular tunable qubit circuits with strong coupling factor g and a Hamiltonian that offers a σ_{z} type of interaction between qubits.

The present disclosure further relates to a qubit circuit comprising at least first and second data qubits and a mediator qubit coupled to the first and second data qubits in a circuit plane, wherein the first data qubit and the second data qubit are coupled to the mediator qubit by means of respective twist couplers, as exemplified herein, see also FIGS. 3 and 4. Each twist coupler preferably comprises superconducting regions connected by superconducting transmission lines, wherein at least two of the connecting transmission lines cross each other at a line crossing point where the crossing transmission lines are separated by an insulator layer.

The present disclosure further relates to a scalable qubit circuit unit comprising data qubits and mediator qubits coupling the data qubits, the qubit circuit defining a 2D lattice circuit plane, wherein each mediator qubit is coupled to at least two data qubits by means of respective twist couplers, and wherein each data qubit is coupled to at least two mediator qubits by means of respective twist couplers, i.e. at least two of the connecting transmission lines cross each other at a line crossing point where the crossing transmission lines are separated by an insulator layer. This scalable qubit circuit unit is defined herein as a plaquette and can be extended all over the 2D circuit plane in a compact manner.

A preferred embodiment of these qubit circuits relates to a tunable qubit circuit configured such that a coupling interaction between the data qubits can be controlled by applying a microwave signal to the mediator qubit while a magnetic flux generated by in-plane bias lines is applied perpendicular to the circuit plane to operate the circuit. The in-plane bias lines might be from the same material as the superconductor comprising the qubits and the microwave.

Qubit error correction is mandatory in the noisy intermediate scale quantum regime, where the current superconductor qubit field operates. Physical errors must be detected and corrected before the encoded quantum information is irreversibly corrupted, and it is therefore crucial that the quantum states can be measured quickly and reliably. Examples of error correction codes include the 9-qubit Shor code and surface codes (2D and 3D).

Surface code error correction measures the parity of adjacent qubits to detect undesired quantum states corruption, which involves measuring a four qubit operator. Since most quantum hardware only support single and two-qubit gates to high fidelity such measurements require the application of at least four two-qubit gates, making the process time consuming and prone to generate errors. The ability to perform multi-qubit operations between more than two qubits extends to fields such as the simulation of lattice gauge theories and quantum optimization schemes. The presently disclosed twist coupler is therefore an advancement for the application of surface code error correction as it allows to measure, in a single measurement, the parity of a plurality of qubits, saving processing time and increasing the fidelity of the computation.

Simulations of the Hamiltonian interaction defining the presently disclosed twist coupler have been performed, and they predict a strong coupling interaction factor “g” between qubits of 500 hMHz. Since the operation time to perform qubit-qubit operations is inversely proportional to the coupling constant ˜1/g the twist coupler allows faster operations, translating into more reliable calculations.

The presently disclosed tunable qubit therefore makes it possible to perform single shot parity operations, and the the present disclosure therefore further relates to a method for performing single shot measurement of the qubits in the tuneable qubit circuit described herein, wherein the magnetic field and the microwave signal are controlled to perform parity operations on the data qubits coupled to the mediator qubit.

### DESCRIPTION OF DRAWINGS

The invention will in the following be described in greater detail with reference to the accompanying drawings:

FIG. 1 shows a circuit sketch of three qubits coupled via twist couplers.

FIG. 2 shows an additional circuit sketch of three qubits coupled via twist couplers.

FIG. 3 shows a sketch of deposited superconducting islands and transmission lines design defining four qubits coupled via twist couplers.

FIG. 4 shows the flux dependence of the coupling strengths and qubit frequencies. Two qubit operations on the outer qubits are run at the coupling degeneracy point where g₁=g₂=g.

FIG. 5 shows a simulation of the qubit driving frequency ω and coupling strength g as a function of the applied magnetic flux to the structure.

FIG. 6 shows a circuit diagram of a plaquette comprising five qubits coupled via twist couplers, as in FIG. 1, where “1”, “2”, “3” and “4” are qubits used to store and perform qubit operations, all four data qubits coupled to a central qubit defined as the mediator (“M”) qubit.

### DETAILED DESCRIPTION

The present disclosure relates to an scalable tunable coupler for superconducting qubits that offers a high coupling factor g and a σ_{z} qubit-qubit interaction Hamiltonian.

As stated previously the present disclosure relates to a scalable qubit circuit unit comprising data qubits and mediator qubits coupling the data qubits, the qubit circuit defining a 2D lattice circuit plane, wherein each mediator qubit is coupled to at least two data qubits by means of respective twist couplers, and wherein each data qubit is coupled to at least two mediator qubits by means of respective twist couplers,

The scalable qubit circuit unit makes it possible to provide a tuneable qubit circuit, configured such that a coupling interaction between the data qubits is tuned by applying a microwave signal to the mediator qubit while a magnetic field generated by in-plane bias lines is applied perpendicular to the circuit plane. The tuneable qubit circuit is preferably configured such that the magnetic field and the microwave signal can be controlled to realise a coupling strength between two qubits of at least 100 hMHz, preferably higher than 200 hMHz and more preferably higher than 500 hMHz.

This coupling interaction makes it possible to realize a method for performing single shot measurement of the qubits in the tuneable qubit circuit, wherein the magnetic field and the microwave signal are controlled to perform parity operations on the data qubits coupled to the mediator qubit. Alternative or additionally single shot measurement of the qubits in the tuneable qubit circuit can be performed, such that the magnetic field and the microwave signal are controlled to perform data qubit to data qubit operations.

The coupling interaction arises because of the non-linearity of the Josephson junctions inductance, the same mechanism that gives rise to the anharmonicity of this type of transmon qubits. Hence, the coupling strength is of the same order as the anharmonicity, which is typically around a few hundred hMHz such as 500 hMHz. This is significantly larger than the typical coupling is strength of transmons qubits which is on the order of tens of hMHz.

With a plurality of these qubit circuits a scalable quantum circuit can be provided that can be configured to perform parity operations for applications such as 2D and 3D surface code qubit error correction, simulation of lattice gauge theories or quantum optimization.

The presently disclosed qubit circuits makes it furthermore possible to provide a scalable superconductor circuit comprising a plurality of the qubit circuits, wherein the qubit circuits are connected as plaquettes in a circuit plane, wherein the data qubits are located at the corners of each plaquette and directly coupled to mediator qubits located at the center of each plaquette by means of twist couplers, such that the plaquettes tesselate the plane. In one example each mediator qubit is directly coupled to three data qubits such that each plaquette is triangular. Alternatively each mediator qubit is directly coupled to four data qubits such that each plaquette is square. And yet again each mediator qubit is directly coupled to six data qubits such that each plaquette is hexagonal. It is noted that two-dimensional planes of qubits coupled via twist couplers can be stacked and coupled in the third dimensions to realize a 3D circuit structure.

As stated above the present disclosure presents a novel qubit coupler in the form of a twist coupler for coupling two superconductor qubits comprising superconducting regions connected by superconducting transmission lines, wherein at least two of the connecting transmission lines cross each other at a line crossing point where the crossing transmission lines are separated by an insulator layer. The superconducting regions and the transmission lines may be provided on a substrate as (selective deposition) layers, for example having a thickness of between 5 and 200 nm, and optionally a length between 1 and 100 μm. The length is designed such as the qubits can be scaled in a chip while still allowing a simple manipulation by eventual contact gates. The insulator layer(s) may have a thickness of less than 30 nm. The target thickness of the insulator takes into account an eventual native oxidation of metallic Al in contact with the atmosphere. Such native oxidation typically comprises the first ˜5 nm of a metallic Al deposition. Also, the maximum thickness of the insulator layer(s) is lower than the maximum thickness at which the underneath devices cannot be manipulated by eventual top contact gates deposited on top of the structure for its manipulation. The superconductor may be selected from the group of metallic superconductors, e.g. Al, Pb an Nb.

### Formation of Superstructure

The fabrication steps of an exemplary twist coupler (for a pair of qubits) may comprise: providing a substrate, such as a planar substrate; forming at least one feature comprising an elongated part to be used as transmission line connected to a pad, both made of a superconductor; wherein the structures are formed e.g. by metallic deposition, sputtering, molecular beam epitaxy growth; delivery of an insulating layer on top of the superconducting feature(s) by methods of metal oxidation process of the topmost layer of the superconductor structures, atomic layer deposition of oxides or in-situ molecular beam epitaxy oxidation; deposition of at least one superconductor feature on top of the insulating layer comprising an elongated part transmission line connected to a pad, both made of a superconductor, wherein the transmission line crosses orthogonally the one deposited in the first step and both separated by the insulating layer forming a Josephson junction; and repeating the previous steps forming a superstructure wherein the transmission lines are superposing each other in a desired sequence and separated by insulating layers.

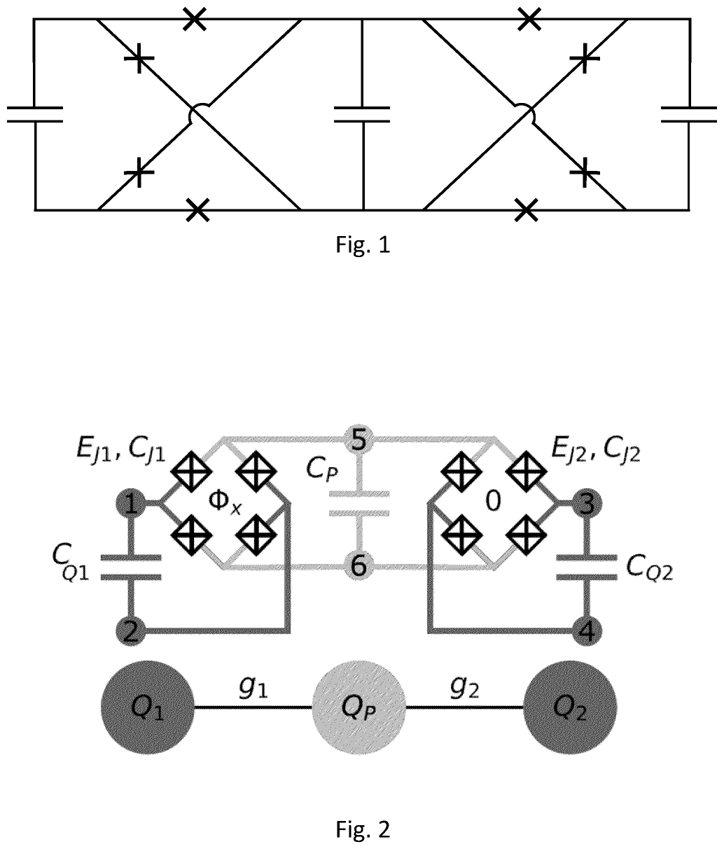

According to a preferred embodiment, a superstructure can be formed by sequentially repeating a selective deposition of a thin metallic superconductor layer on a planar substrate and a series of metal oxidation steps. The selective deposition may define at least one elongated part transmission line connected to a pad, creating the physical housing of a superconducting qubit. Preferably, an oxidation step generates an insulating layer on top of the defined structures. Subsequent metallic superconductor selective depositions allow to deposit additional elongated parts transmission lines connected to pads, wherein the later transmission lines orthogonally cross the former ones, separated by an insulating layer. The amount of deposited features is arbitrarily designed. A schematic design of the circuit is sketched in FIG. 1, describing three qubits coupled via twist couplers, each of them having a crossing point of transmission lines. For each crossing point of transmission lines described in FIG. 1 it is required to perform a metal oxidation step of the first ˜10 nm of the deposition in order to avoid electrical contact between the crossing transmission lines.

FIG. 2 shows an additional schematic design of a circuit comprising three qubits coupled by twist couplers. The design is an additional possible realization of three qubits coupled via twist couplers and it is geometrically equivalent to the one presented in FIG. 1. In FIG. 2 Q₁ and Q₂ are data qubits and Q_{P} is a mediator qubit. Each qubit comprises a capacitor with a capacity C_{Q,P} and each contact point between qubits is performed through Josephson junctions having a characteristic energy E and capacitance C_{J}. A magnetic flux Φ might be applied through the closed loop generated by the Josephson junctions comprising each twist coupler. Similarly to FIG. 1, a number of transmission lines cross each other. The fabrication of the crossing point requires an oxidation step between the depositions defining each line to avoid electrical contact between both.

In FIGS. 1 and 2, the precise design of Josephson junctions forming a closed loop and the location of the transmission lines connecting each loop is an example of what defines the presently disclosed twist coupler and its novel properties. Due to the geometry of the disclosed design of the twist coupler, it is possible to scale up the size of the circuit described in FIGS. 1 and 2, allowing to fabricate a 2D circuit comprised of a plurality of data qubits coupled to mediator qubits through twist couplers.

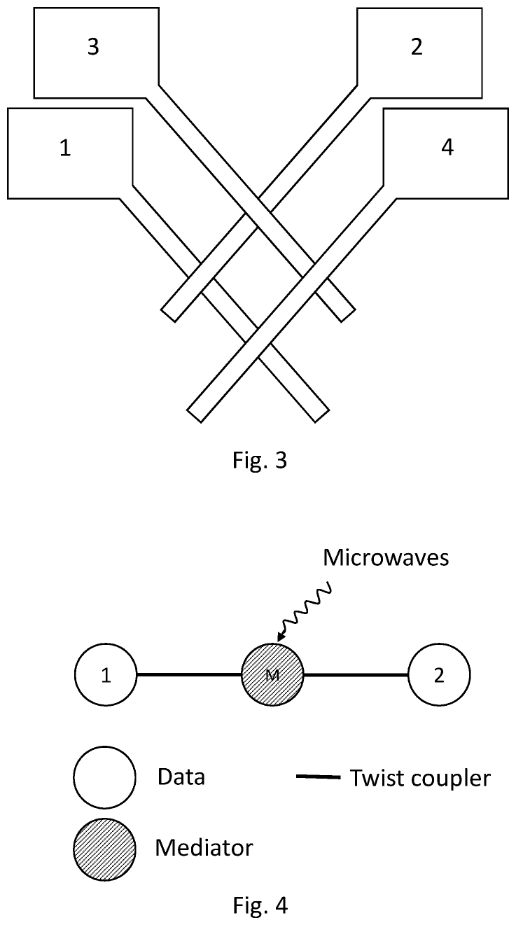

A preferred embodiment may comprise four deposited features, defining four superconducting qubits coupled via superposing Josephson junctions, as shown in FIG. 3. The disclosed method may be utilized to produce a highly scalable Josephson ring modulator device architecture for quantum transport applications.

Accordingly, the presently disclosed method provides a technique to controllably mass-produce superconducting coupled circuits. The method works for many different materials and provides a scalable method to realize high coupling factor and quantum transistors.

The first step of the method disclosed above is the provision of a substrate, e.g. a planar substrate, which may include any substrate, preferably a substrate suitable for fabricating high-end nanocircuits. Examples include III/V substrates such as InAs, GaAs, GaN, GaSb, and InP, but also IV substrates such as Si, Ge, and SiGe. Other substrates such as sapphire substrates may also be utilized.

The second step of the method is the formation of at least one feature comprising a superconductor elongated part connected to a superconductor pad. A superstructure should be understood herein as any structure provided on a substrate. In one embodiment, the superstructure is formed by selective deposition of a superconductor on a planar substrate.

In one embodiment, the superconducting superstructure may be delivered by any known physical or chemical thin film nanofabrication technique such as metallic sputtering, metallic evaporation, plasma enhanced chemical vapour deposition or atomic layer deposition. Other techniques such as crystal growth techniques may be used, such as molecular beam epitaxy or chemical vapour deposition. The selection of a technique may lead to the generation of superconductor crystal island of different size, purity, film rugosity and impurity density. The superconducting material may comprise a pure element (e.g. Al, Pb, V, Sn, or In), an alloy (e.g. NbTi or NbTiN), a ceramic such as a cuprate (e.g. YBa2Cu3O7 or CuO2), an iron-based superconductor, a covalent superconductor, or magnesium diboride (MgB2). Examples of superconductors formed by a pure element includes: Bi, Cd, Ga, In, Hf, Hg, La, Os, Pa, Re, Ru, Tc, Ti, Tl, U, Zn, Zr, B, N, O, Mg, Ge, Y, Sm, As, F, P, Se, Gd, Ni, Pd, Ag, Pt, Au, Ac, Cr, and Eu. In particular, the following list of superconducting materials are preferred in some embodiments of the presently disclosed method: Al, Pb, NbTlN, NbTi, V, Sn, MgB2, In, and AlPt. The superconducting material may be crystalline structured. The insulating material may comprise a native oxide of the deposited metal generated by surface oxidation, such as AlOx or PbOx, or ex-situ deposition of a different material such as SiOx or AlOx via atomic layer deposition.

The delivery of the insulating layers between the different superconductor structures can be performed by in-situ metal oxidation of the topmost layer of the superconductor or by deposition of an insulator. The insulator may be the correspondent native oxide of the superconductor in questions if it has desired material properties for Josephson junction fabrication or a non-native oxide that is delivered via any deposition technique.

In another embodiment of the disclosed method, the superstructure is grown such that a number of said elongation crosses over a number other elongations from other superstructures, separated by a conductively interconnected at least partially along their growth direction (see FIG. 3). For the given embodiment in FIG. 3, the structure generation sequence was structure 1, 2, 3 and 4, performing an oxidation step in between each metallic deposition. Such inter-connection between different qubits with the distinct cross of elongated features is defined as “twist coupler” between qubits from now on.

A structure defining a qubit may have a superconductor pad of dimensions 100 by 300 nm and the elongated part may have dimensions of 20 μm by 100 nm, as seen in the sketch of FIG. 3. The origin place and angle of the elongated part from the pad is not restricted to any place in particular.

### Physical Properties of Twist Couplers

The effective Hamiltonian describing the physics of the presently disclosed twist coupler is proportional to the Pauli matrix σ_{z} and the coupler is capable of realizing a strong coupling factor g between qubits. These facts allow to perform multiple data qubit parity single shot measurements due to the σ_{z} dependence, each gate measurement in a short period of time t∝1/g.

Simulations show typical coupling factors g achieved by using twist couplers of up to 500 hMHz, which is remarkably higher than comparable prior art devices. A high coupling factor g allows a fast gate operation of the qubits, which together with the ability of performing single shot parity measurements vastly decreases the gate operation times needed to run surface code qubit error corrections.

### Manipulating the Qubits

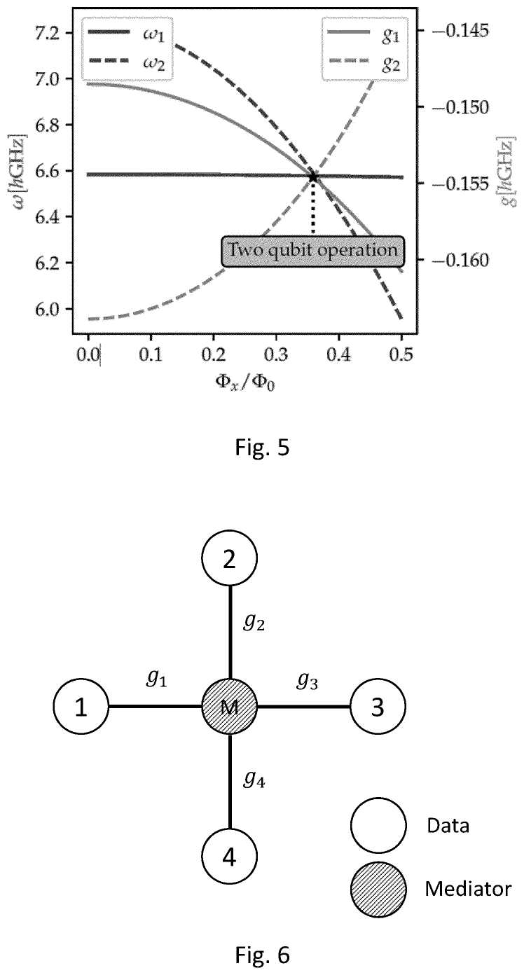

A magnetic field needed to tune the qubits and their interactions can be applied through on-chip bias lines. A material comprising these on-chip bias lines can be the same as the superconducting islands deposited to define the qubits and be deposited during any of the deposition steps. A usual current running from these bias lines is in the order of ˜ HA, generating enough magnetic field to tune the qubits. However, a maximum current limit should not be surpassed as the bias lines can dissipate heat into the cryostat inducing and undesired increase of temperature. The final flux contained inside a superconducting loop will be dependent on the area of the loop, which is the variable plotted in the x-axis of FIG. 5.

Microwaves with a frequency between 4 and 10 hGHz can be applied to the data qubits to tune them, through nano-capacitor devices placed nearby. FIG. 5 shows the flux dependence of the coupling strengths and qubit applied frequencies. A resulting coupling factor g of ˜0.15 hGHz between the data qubits and the mediator qubit is achieved at the degeneracy point of ω₁=ω₂. This strong coupling, compared to prior art devices, allows to effectively control the interaction between data qubits, where a close to 0 interaction (decoupled stated) can be achieved, solving a problem in the realization of a universal quantum computer.

### Scalable Design

A plaquette is a scalable circuit unit formed by a number of data qubits and a mediator qubit coupled to them. The shape of the plaquette can be triangular, square, hexagonal or any other geometrical shape that can tessellate the circuit plane. The site qubits placed in the vertex of the plaquette are data qubits used to perform calculations, while the central site qubits are ancillary mediator qubits. Due to the coupling between mediator and data qubits, the mediator transition frequency effectively depends on the state of the adjacent data qubits. This allows for multi-qubit gates and measurements to be performed on the data qubits by driving the mediator qubit at specific frequencies.

FIG. 5 shows a sketch of a plaquette circuit unit comprising 4 data qubits coupled to a central mediator qubit via twist couplers. This arrangement of qubits allows to place and connect plaquettes in a circuit plane with a high degree of packing factor. Under this approach, each data qubit will be connected to two mediator qubits enabling the use of software error correction codes such as surface codes and to perform lattice gauge calculations.

In general, the plaquette tessellation of a 2D plane can be extended to the third dimension by stacking in a controlled manner a number of 2D planes and allowing the communication between different layers, allowing to perform the theorized 3D surface codes for qubit error correction.

### Example

In an example embodiment, a twist coupler for coupling two Al superconductor qubits comprises superconducting regions connected by superconducting transmission lines, wherein at least two of the connecting transmission lines cross each other at a line crossing point where the crossing transmission lines are separated by an insulator AlOx layer, wherein the superconducting regions and the transmission lines are provided on an InAs or sapphire substrate as (selective deposition) layers having a thickness of 25 nm and a length of 10 μm, and wherein the insulator layer(s) has a thickness of ˜10 nm.

Preferably, the length of the deposition is high enough to allow an quick electrical contact bonding of the devices and low enough to allow to scale up the number of devices within a chip. The thickness of the oxide is selected taking into account a native oxidation of the previously deposited metallic Al of ˜5 nm occurring when Al is put in contact with the atmosphere.

### Items

1. A qubit circuit comprising at least first and second data qubits and a mediator qubit coupling the first and second data qubits in a circuit plane, wherein the first data qubit and the second data qubit are coupled to the mediator qubit by means of respective twist couplers, each twist coupler comprising superconducting regions connected by superconducting transmission lines, wherein at least two of the connecting transmission lines cross each other at a line crossing point where the crossing transmission lines are separated by an insulator layer.
2. A qubit circuit comprising data qubits and mediator qubits coupling the data qubits, the qubit circuit defining a 2D lattice circuit plane, wherein each mediator qubit is coupled to at least two data qubits by means of respective twist couplers, and wherein each data qubit is coupled to at least two mediator qubits by means of respective twist couplers, each twist coupler comprising superconducting regions connected by superconducting transmission lines, wherein at least two of the connecting transmission lines cross each other at a line crossing point where the crossing transmission lines are separated by an insulator layer.
3. A tuneable qubit circuit comprising the qubit circuit according to any of items 1-2, configured such that a coupling interaction between the data qubits is tuned by applying a microwave signal to the mediator qubit while a magnetic field generated by in-plane bias lines is applied perpendicular to the circuit plane.
4. A tuneable qubit circuit according to item 3, configured such that the magnetic field and the microwave signal can be controlled to realise a coupling strength between two qubits of at least 100 hMHz.
5. A method for performing single shot measurement of the qubits in the tuneable qubit circuit according to item 3, wherein the magnetic field and the microwave signal are controlled to perform parity operations on the data qubits coupled to the mediator qubit.
6. A method for performing single shot measurement of the qubits in the tuneable qubit circuit according to item 3, wherein the magnetic field and the microwave signal are controlled to perform data qubit to data qubit operations.
7. A scalable quantum circuit comprising a plurality of the qubit circuits according to any of items 2-4, configured to perform parity operations for applications such as 2D and 3D surface code qubit error correction, simulation of lattice gauge theories or quantum optimization.
8. A scalable superconductor circuit comprising a plurality of the qubit circuits of any of items 2-4, wherein the qubit circuits are connected as plaquettes in a circuit plane, wherein the data qubits are located at the corners of each plaquette and directly couple to mediators located at the center of each plaquette using twist couplings, such that the plaquettes tesselate the plane.
9. The scalable superconductor circuit of item 8, wherein each mediator qubit is directly coupled to three data qubits such that each plaquette is triangular.
10. The scalable superconductor circuit of item 8, wherein each mediator qubit is directly coupled to four data qubits such that each plaquette is square.
11. The scalable superconductor circuit of item 8, wherein each mediator qubit is directly coupled to six data qubits such that each plaquette is hexagonal.
12. A twist coupler for coupling two superconductor qubits comprising superconducting regions connected by superconducting transmission lines, wherein at least two of the connecting transmission lines cross each other at a line crossing point where the crossing transmission lines are separated by an insulator layer, wherein the superconducting regions and the transmission lines are provided on a substrate as (selective deposition) layers having a thickness of between 5 and 200 nm and a length between 1 and 100 μm, and wherein the insulator layer(s) has a thickness of less than 30 nm.
13. The superconductor of item 12, wherein the superconductor is selected from the group of AI, Pb an No.
14. A qubit circuit comprising at least two qubits coupled by means of the twist coupler according to any of items 12-13.
15. The qubit circuit according to any of items 1-4, wherein the twist coupler are the twist coupler according to any of items 12-14.

1. A qubit circuit comprising at least a first and a second data qubits and a mediator qubit coupling the first and second data qubits in a circuit plane, wherein the first data qubit and the second data qubit are coupled to the mediator qubit by means of respective twist couplers, each twist coupler comprising superconducting regions connected to superconducting transmission lines, wherein at least two of the connecting transmission lines cross each other at a line crossing point where the crossing transmission lines are separated by an insulator layer.

2. The qubit circuit according to claim 1, wherein the mediator qubit is coupled to at least two data qubits by means of respective twist couplers and wherein each data qubit is coupled to at least two mediator qubits by means of respective twist couplers, defining a 2D lattice circuit plane.

3. The qubit circuit according to claim 1, configured such that a coupling interaction between the data qubits is tuned by applying a microwave signal to the mediator qubit while a magnetic field generated by in-plane bias lines is applied perpendicular to the circuit plane.

4. The qubit circuit according to claim 3, wherein the applied magnetic field and the microwave signal are configured to generate a coupling strength between two qubits.

5. The qubit circuit according to claim 4, wherein the coupling strength between two qubits is at least 100 hMHz, preferably at least 150 hMHz, more preferably at least 250 hMHz or even more preferably at least 500 hMHz.

6. The qubit circuit according to claim 3, wherein the mediator qubits controlled by the magnetic field are configured to perform single shot measurements of the qubits, wherein the magnetic field and the microwave signal are controlled to perform parity operations on the data qubits coupled to the mediator qubits.

7. The qubit circuit according to claim 3, wherein the data qubits controlled by the microwave signals are configured to perform data qubit to data qubit operations.

8. A scalable quantum circuit comprising a plurality of the qubit circuits according to claim 2.

9. The scalable quantum circuit according to claim 8, configured to perform parity operations for 2D and 3D surface code qubit error correction, simulation of lattice gauge theories or quantum optimization.

10. The scalable quantum circuit according to claim 8, wherein the qubit circuits are connected defining plaquettes in a circuit plane, wherein the data qubits are located at the corners of each plaquette and directly coupled to mediator qubits located at the center of each plaquette using twist couplers, such that the plaquettes tesselate the plane.

11. The scalable quantum circuit according to claim 8, wherein each mediator qubit directly coupled to three data qubits define a triangular plaquette.

12. The scalable quantum circuit according to claim 8, wherein each mediator qubit directly coupled to four data qubits define a square plaquette.

13. The scalable quantum circuit according to claim 8, wherein each mediator qubit directly coupled to six data qubits define a hexagonal plaquette.

14. A twist coupler for coupling two superconductor qubits comprising superconducting regions connected to superconducting transmission lines, wherein at least two of the connecting transmission lines cross each other at a line crossing point where the crossing transmission lines are separated by an insulator layer, wherein the superconducting regions and the transmission lines are provided on a substrate as (selective deposition) layers having a thickness of between 5 and 200 nm and a length between 1 and 100 μm, and wherein the insulator layer(s) has a thickness of less than 30 nm.

15. The twist coupler according to claim 14, wherein the superconductor is selected from the group of metallic superconductors.

16. The twist coupler according to claim 14, wherein the superconductor is selected from the group of Al, Pb an Nb.

17. The qubit circuit according to claim 1, comprising at least two data qubits coupled by a twist coupler, wherein the superconducting regions of the twist coupler and the transmission lines are provided on a substrate as (selective deposition) layers having a thickness of between 5 and 200 nm and a length between 1 and 100 μm, and wherein the insulator layer(s) has a thickness of less than 30 nm.

18. The qubit circuit according to claim 1, wherein the superconducting regions of the twist coupler and the transmission lines are provided on a substrate as (selective deposition) layers having a thickness of between 5 and 200 nm and a length between 1 and 100 μm, and wherein the insulator layer(s) has a thickness of less than 30 nm.
